(19) United States
(12) Patent Application Publication
(10) Pub. No.: US 2021/0165034 A1
(43) Pub. Date: Jun. 3, 2021

(54) BYPASS THYRISTOR VALVE GROUP INSPECTION METHOD AND CONTROL APPARATUS

(71) Applicants: NR ELECTRIC CO., LTD, Nanjing (CN); NR ENGINEERING CO., LTD, Nanjing (CN)

(72) Inventors: Dongbin LU, Nanjing (CN); Hua HUANG, Nanjing (CN); Weiming PAN, Nanjing (CN); Shengfu GAO, Nanjing (CN); Lei LIU, Nanjing (CN); Fan YANG, Nanjing (CN)

(21) Appl. No.: 16/771,137

(22) PCT Filed: Feb. 21, 2019
(86) PCT No.: PCT/CN2019/075672

§ 371 Date: Jun. 9, 2020

(30) Foreign Application Priority Data
Mar. 5, 2018 (CN) 201810178405.2

(51) Int. Cl. G01R 31/26; H02H 7/12; G01R 31/327

(52) U.S. Cl. CPC G01R 31/263; G01R 31/3277; H02H 7/1203

(57) ABSTRACT

The present invention discloses a bypass thyristor valve group inspection method and control apparatus for inspecting sub-modules in a bypass thyristor valve group, and in particular, including: dividing the bypass thyristor valve group into N sub-modules, where N is greater than or equal to 2, N is a natural number, and each sub-module is formed by connecting one or more thyristors in series; under the condition that the bypass thyristor valve group bears a normal forward voltage, sequentially triggering, by the bypass thyristor valve group control apparatus, the sub-modules according to a certain time period; detecting whether the sub-modules are capable of operating normally or not; and if not, sending an alarm signal. According to the bypass thyristor valve group inspection method and control apparatus, the problem of thyristor performance monitoring under the condition that the bypass thyristor valve group does not operate for a long time is effectively solved, and safety in operation of a protected voltage source current converter is guaranteed.

### TECHNICAL FIELD

The present invention relates to the field of High Voltage Direct Current (HVDC) transmission employing Voltage-Source Converters (VSCs) and HVDC transmission employing Line Commutated Converters (LCCs), and in particular, to a bypass thyristor valve group inspection method and control apparatus.

### BACKGROUND

Voltage Source Converter based High Voltage Direct Current Transmission (VSC-HVDC) has the advantages that the controllability is high, a passive system can be accessed, and no reactive power compensation apparatus is needed, and has the disadvantages that the converter has large switching loss, and when an alternating current (AC) system or converter on the inverter side has a fault, especially when a valve region between the converter and a converter transformer has a fault, a large voltage and current impact can be generated to the converter, and more seriously, the converter may even be damaged. In order to avoid the impact of DC voltage and DC current caused by a rectifier side, generally, a lightning arrester is connected in parallel to a bridge arm of the voltage source converter, which requires a large capacity, and thus it is difficult for engineering implementation. The patent with the application No.: CN201510010158.1 and entitled “Hybrid HVDC Converter and HVDC Apparatus” provides a hybrid HVDC converter, in which a voltage source type valve group is connected to an inductor and then to a bypass switch in parallel, and the bypass switch is a power electronic switch. According to this solution, the effect of protecting the converter is better, but the power electronic switch needs to be monitored, so that normal turn-on can be ensured under serious fault conditions, thereby protecting the voltage source converter.

### SUMMARY

An objective of the present invention is to provide a bypass thyristor valve group inspection method for inspecting sub-modules, connected in parallel at two ends of a DC side of a voltage source converter, in a bypass thyristor valve group, so as to ensure that the bypass thyristor valve group can be normally conducted under serious fault conditions. Also provided is a bypass thyristor valve group inspection control apparatus for controlling the bypass thyristor valve group to implement the foregoing inspection method.

In order to achieve the foregoing objective, the present invention adopts the following technical solution: a bypass thyristor valve group inspection method for inspecting sub-modules in a bypass thyristor valve group, including: dividing the bypass thyristor valve group into N sub-modules, where N is greater than or equal to 2, N is a natural number, and each sub-module is formed by connecting one or more thyristors in series; under the condition that the bypass thyristor valve group bears a forward voltage during normal operation, sequentially triggering the sub-modules according to a certain time period; detecting whether the sub-modules are capable of operating normally or not; and if not, sending an alarm signal.

In the foregoing solution, the bypass thyristor valve group includes only one bridge arm which is formed by connecting a plurality of thyristors in series, and includes a corresponding control protection circuit. The bypass thyristor valve group is configured to bypass a voltage source converter connected in parallel thereto or a voltage source converter on a parallel branch thereof. The principle of dividing the bypass thyristor valve group into N sub-modules is: when a single sub-module is turned on, the remaining sub-modules which are not turned on can bear a forward voltage during normal operation.

The sequentially triggering the sub-modules according to a certain time period refers to: triggering the sub-modules in sequence or triggering the sub-modules according to a certain probability algorithm, and ensuring that each sub-module is triggered at least once in the certain time period, where the certain time period is on the order of second, or minute, or hour, or day, or month, or year.

The detecting whether the sub-modules are capable of operating normally or not is determined based on detecting whether the sub-modules are from an off-state to an on-state, or in an on-state, or from an on-state to an off-state.

The normal operation of the sub-modules refers to the fact that all thyristors in the sub-modules can be normally turned on, or a certain redundancy is set for the sub-modules; if it is detected that the number of thyristors that cannot be turned on in the sub-modules is less than the redundancy, the inspection is continued; and if the bypass thyristor valve group is required to put into operation, the thyristors that cannot be turned on implement current flowing by means of protective trigger or breakdown.

The voltage source converter is any one or more of: a two-level converter, a diode-clamped multilevel converter, a Modular Multilevel Converter (MMC), a Hybrid Multilevel Converter (HMC), a two-level cascaded converter CSL, or a stacked two-level converter CTL, and consists of a switchable fully-controlled power semiconductor that can be turned off. The fully-controlled power semiconductor that can be turned off is any one or more of: an Insulated Gate Bipolar Transistor (IGBT), an Integrated Gate Commutated Thyristor (IGCT), a Gate-Turn-Off Thyristor (GTO), a Power MOSFET, an Injection Enhanced Gate Transistor (IEGT), a Gate Commutated Thyristor (GCT), or a Silicon Carbide Enhanced Junction Field Effect Transistor (SiC-JFET).

The present invention further provides a bypass thyristor valve group inspection control apparatus for inspecting sub-modules in a bypass thyristor valve group, including a valve group control unit, a valve-based electronic unit, and a thyristor control unit.

The valve group control unit is configured to: divide the bypass thyristor valve group into N sub-modules, where N is greater than or equal to 2, N is a natural number, and each sub-module is formed by connecting one or more thyristors in series; detect a forward voltage born by the bypass thyristor valve group during normal operation; sequentially send a control pulse to the valve-based electronic units of different sub-modules of the bypass thyristor valve group according to a certain time period; receive a sub-module turn-on signal of the valve-based electronic unit; and if no sub-module turn-on signal of the valve-based electronic units is received, send an alarm signal.

The valve-based electronic unit is configured to receive the control pulse of the valve group control unit and a thyristor-born forward voltage signal of the thyristor control unit, receive a thyristor turn-on signal of the thyristor control unit, send a trigger pulse to the thyristor control unit, and send the sub-module turn-on signal to the valve group control unit.

The thyristor control unit includes a control circuit, a powering loop, and a resistance-capacitance discharge loop. The control circuit is configured to receive the trigger pulse of the valve-based electronic unit, send the thyristor-born forward voltage signal to the valve-based electronic unit, and send the thyristor turn-on signal to the valve-based electronic unit. The powering loop at least includes two static voltage-sharing resistors and an energy storage capacitor, and before the thyristor is turned on, enough energy can be obtained to ensure the normal turn-on of the thyristor. The resistance-capacitance discharge loop at least includes a resistor and a capacitor which are connected in series, and after the thyristor is turned on, enough energy can be obtained to ensure the normal turn-on of the thyristor.

The bypass thyristor valve group includes only one bridge arm which is formed by connecting a plurality of thyristors in series, and includes a corresponding control protection circuit. The bypass thyristor valve group is configured to bypass a voltage source converter connected in parallel thereto or a voltage source converter on a parallel branch thereof. The principle of dividing the bypass thyristor valve group into N sub-modules is: when a single sub-module is turned on, the remaining sub-modules which are not turned on can bear a forward voltage during normal operation.

The sequentially sending the control pulse to the valve-based electronic units of different sub-modules of the bypass thyristor valve group according to a certain time period refers to: triggering the sub-modules in sequence or triggering the sub-modules according to a certain probability algorithm, and ensuring that each sub-module is triggered at least once in the certain time period, where the certain time period is on the order of second, or minute, or hour, or day, or month, or year.

The fact that the valve group control unit receives the sub-module turn-on signal of the valve-based electronic unit is that all thyristors in the sub-modules are turned on, or a certain redundancy is set for the sub-modules, and the thyristors that do not exceed the redundancy in the sub-modules are turned on. The fact that the valve group control unit does not receive the sub-module turn-on signal of the valve-based electronic unit is that any one or more thyristors in the sub-modules are not turned on, or the thyristors that exceed the redundancy in the sub-module are not turned on.

The thyristor turn-on signal sent to the valve-based electronic unit by the thyristor control unit refers to that the thyristor-born forward voltage signal disappears, or current flows through the thyristor, or the thyristor-born forward voltage signal reappears. The control circuit of the thyristor control unit has a protective trigger function, and if the thyristor does not receive the trigger pulse of the valve-based electronic unit, before being broken down, the thyristor is subjected to protective trigger.

The present invention has the following beneficial effects: provided are a bypass thyristor valve group inspection method and control apparatus for detecting the state of each sub-module of a bypass thyristor valve group when the bypass thyristor valve group is not turned on, and sending an alarm signal if the state of the sub-module is abnormal, and the problem of thyristor performance monitoring under the condition that the bypass thyristor valve group does not operate for a long time is effectively solved.

### BRIEF DESCRIPTION OF THE DRAWINGS

FIG. 1 illustrates a hybrid HVDC transmission circuit structure with a sending end based on a line commutated converter and a receiving end based on a voltage source converter;

FIG. 2 illustrates a hybrid HVDC transmission circuit structure with a sending end based on two line commutated converters and a receiving end based on a line commutated converter and a voltage source converter;

FIG. 3 is a bypass thyristor valve group inspection method according to the present invention;

FIG. 4 is a bypass thyristor valve group inspection control apparatus according to the present invention; and

FIG. 5 is a thyristor control unit circuit according to the present invention.

### DETAILED DESCRIPTION

Embodiments of the present invention are described with reference to the following drawings, and the same components are numbered with the same reference numerals.

For the VSC-HVDC transmission system, when the AC system or converter on the inverter side has a fault, especially when a valve region between the converter and a converter transformer has a fault, a large voltage and current impact can be generated to the converter, and more seriously, the converter may even be damaged. In order to avoid the impact of DC voltage and DC current caused by a rectifier side, a bypass power electronic switch, e.g., a bypass thyristor valve group is connected in parallel to two ends of a DC side of the voltage source converter. The bypass thyristor valve group connected in parallel to two ends of the DC side of the voltage source converter is turned on for discharging only under serious fault conditions, and is not turned on during normal operation. Therefore, in order to ensure that the bypass thyristor valve group is always in a normal state, the bypass thyristor valve group is detected according to a certain time period, thereby ensuring normal turn-on under serious fault conditions, and protecting the voltage source converter.

FIG. 1 illustrates a hybrid HVDC transmission embodiment with a sending end based on a line commutated converter and a receiving end based on a voltage source converter. A line commutated converter 7 on the rectifier side converts the AC power of an AC system 8 into DC power via a converter transformer 10, and the DC power is sent to a voltage source converter 1 on the inverter side through a current limiting reactor 4 via a DC line 5, and is converted into AC power via a main transformer 11 and then sent to an AC system 9. The line commutated converter 7 is a six-pulse bridge circuit or a twelve-pulse bridge circuit, which consists of semi-controlled power semiconductors which cannot be turned off, generally, thyristors which cannot be turned off. The voltage source converter 1 is a two-level converter, a diode-clamped multilevel converter, an MMC, an HMC, a CSL, or a CTL, and consists of a fully-controlled power semiconductor that can be turned off, such as an IGBT or an IGCT.

When a minor fault occurs in the AC system 9, and the voltage source converter 1 does not need to block, for example, a single-phase AC ground fault, after detecting overvoltage or overcurrent, the line commutated converter 7 on the rectifier side adjusts a trigger angle to inhibit DC from increasing, and the overvoltage or overcurrent can be eliminated through the control capability of the rectifier side.

When a serious fault occurs in the AC system 9, and the voltage source converter 2 needs to block, for example, a three-phase AC short-circuit fault, the power of the voltage source converter 1 on the inverter side cannot be normally sent out, and the line commutated converter 7 on the rectifier side continues to charge the voltage source converter 1 on the inverter side due to the relatively slow angle adjustment of the line commutated converter on the rectifier side, which causes serious overvoltage and overcurrent to the voltage source converter 1 on the inverter side. In order to avoid damaging the voltage source converter 1 on the inverter side, after it is detected that a serious fault occurs in the AC system 9 or the voltage or current of the converter exceeds a threshold, a bypass thyristor valve group 2 is triggered to turn on, a connection switch 3 between the bypass thyristor valve group 2 and the voltage source converter 1 is turned off, and the current of the bypass thyristor valve group 2 is controlled to zero to be off by retard of the line commutated converter 7 on the rectifier side; after the fault disappears, the connection switch 3 between the thyristor valve group 2 and the voltage source converter 1 is turned on, and the voltage source converter 1 is connected. In order to ensure that the bypass thyristor valve group 2 is quickly and reliably turned off, a switch 6 on a neutral line of a main loop can be turned off when the DC current is low or zero, and the switch 6 is then turned on after the current is zero.

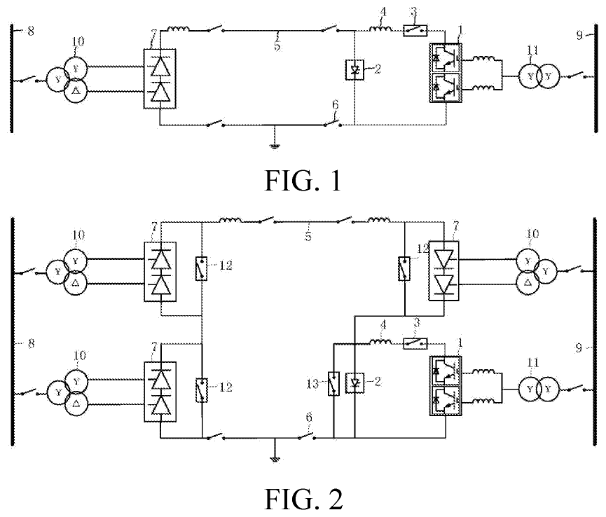

FIG. 2 illustrates a hybrid HVDC transmission embodiment with a sending end based on a line commutated converter series structure and a receiving end based on a line commutated converter and a voltage source converter which are connected in series. The line commutated converter 7 on the rectifier side converts the AC power of the AC system 8 into DC power via the converter transformer 10, and the DC power is sent to a line commutated converter 7 on the inverter side and the voltage source converter 1 via the DC line 5, and is converted into AC power via the main transformer 11 and then sent to the AC system 9. On the inverter side, a cathode of the line commutated converter 7 is connected to an anode of the voltage source converter 1.

When a minor fault occurs in the AC system 9, and the voltage source converter 1 does not need to block, for example, a single-phase AC ground fault, the line commutated converter 7 on the inverter side has a fault during commutation, and the voltage source converter 1 implements fault ride-through, and after receiving fault information sent by the inverter side, the line commutated converter on the rectifier side adjusts the trigger angle to inhibit the DC from increasing, and the overvoltage or overcurrent can be eliminated through the control capability of the rectifier side.

When a serious fault occurs in the AC system 9, and the voltage source converter 1 needs to block, if it is a transient self-recovery fault, for example, a three-phase AC transient short-circuit fault, the power of the voltage source converter 1 on the inverter side cannot be normally sent out transiently, the line commutated converter 7 on the inverter side cannot send the power out due to the relatively slow angle adjustment of the line commutated converter 7 on the rectifier side, and the line commutated converter 7 on the rectifier side only charges the voltage source converter 1 on the inverter side, which causes a more serious overvoltage and overcurrent phenomenon to the voltage source converter 1 on the inverter side. In order to avoid damaging the voltage source converter 1 on the inverter side, after it is detected that the voltage or current of the converter exceeds a threshold due to the fact that a serious fault occurs in the AC system, the bypass thyristor valve group 2 is triggered to turn on, the connection switch 3 between the bypass thyristor valve group 2 and the voltage source converter 1 is turned off, and the current of the bypass thyristor valve group 2 is controlled to zero to be off by retard of the line commutated converter 7 on the rectifier side; after the fault disappears, the connection switch 3 between the thyristor valve group 2 and the voltage source converter 1 is turned on, and the voltage source converter 1 is connected. In order to ensure that the bypass thyristor valve group 2 is quickly and reliably turned off, the switch 6 on the neutral line of the main circuit can be turned off when the DC current is low or zero, and the switch 6 is then turned on after the current is zero.

When a serious fault occurs in the voltage source converter 1, and the voltage source converter 1 needs to block, if it is not a transient self-recovery fault, for example, a fault of the converter itself, the voltage source converter 1 needs to block, the bypass thyristor valve group 2 is triggered to turn on, and the connection switch 3 between the bypass thyristor valve group 2 and the voltage source converter 1 is turned off. In order to ensure that the line commutated converter 7 continues to operate, current continue to flow through the bypass thyristor valve group 2, or a bypass switch 13 is turned on to provide a current path. When a serious fault occurs in the AC system 9 or the line commutated converter 7 on the inverter side, and the line commutated converter 7 needs to block, a bypass pair of the line commutated converter 7 is triggered to turn on, and a bypass switch 12 is turned on to provide a current path for the voltage source converter 1.

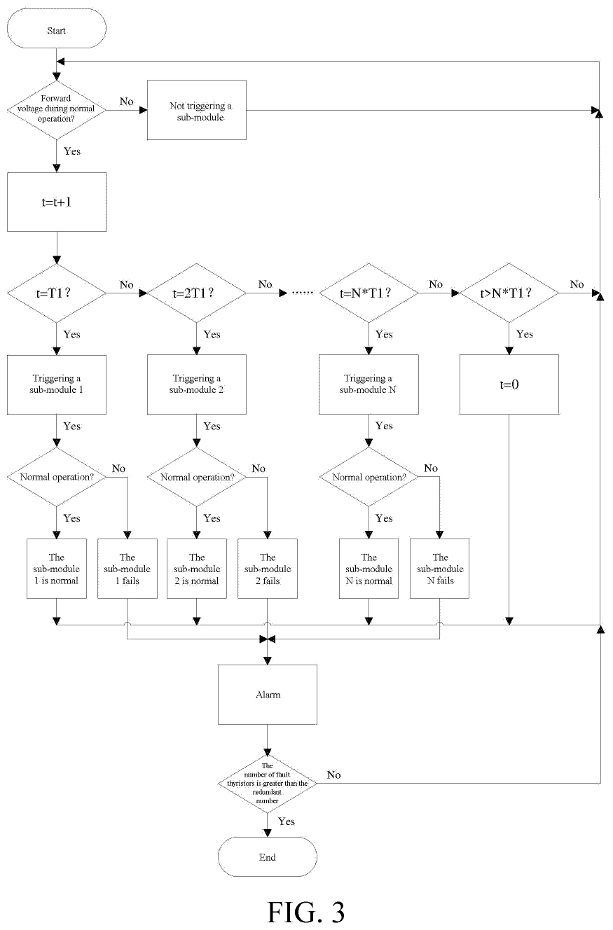

FIG. 3 is a bypass thyristor valve group inspection method according to the present invention, including: inspecting the voltage source converter 1 or the bypass thyristor valve group 2 connected in parallel to a series branch of the voltage source converter 1 in FIGS. 1 and 2, and dividing the bypass thyristor valve group into N sub-modules, where each sub-module is formed by connecting one or more thyristors in series, and when a single sub-module is turned on, the remaining sub-modules can bear a forward voltage during normal operation. A program is initialized, and a counter t=0, if the bypass thyristor valve group bears the forward voltage during normal operation, the counter starts to increase from t, if t is increased to T1, then a sub-module 1 is triggered, if the sub-module 1 is normally turned on, the remaining sub-modules continue to be inspected, if the sub-module 1 has a fault, an alarm signal indicating that the sub-module 1 has a fault is sent, and the inspection is stopped; if t is increased to 2*T1, a sub-module 2 is triggered, if the sub-module 2 is normally turned on, the remaining sub-modules continue to be inspected, if the sub-module 2 has a fault, an alarm signal indicating that the sub-module 2 has a fault is sent, and the inspection is stopped; if there is no fault, t continues to increase, if t is increased to N*T1, a sub-module N is triggered, if the sub-module N is normally turned on, the remaining sub-modules continue to be inspected, if the sub-module N has a fault, an alarm signal indicating that the sub-module N has a fault is sent, and the inspection is stopped; and if t>N*T1, t=0, and the sub-module 1 is re-inspected. If the bypass thyristor valve group bears a lower forward voltage, the sub-module is not triggered to be turned on, and a low voltage alarm signal is sent. If the bypass thyristor valve group bears a higher forward voltage, which is lower than a fixed value of a bypass thyristor valve group provided, the sub-module is not triggered to be turned on, and a high voltage alarm signal is sent; if the voltage is higher than the fixed value of the bypass thyristor valve group provided, all sub-modules of the bypass thyristor valve group are triggered; and if a command that the bypass thyristor valve group is provided to the voltage source converter is received, the inspection is stopped, and all sub-modules of the bypass thyristor valve group are triggered. The normal turn-on of the sub-module refers to the fact that all thyristors in the sub-module are turned on, or a certain redundancy is set for the sub-module; when it is detected that the number of thyristors that cannot be turned on in the sub-module is less than the redundancy, the inspection is continued; and when the bypass thyristor valve group is required to put into operation, the thyristors that cannot be turned on implement current flowing by means of protective trigger or breakdown.

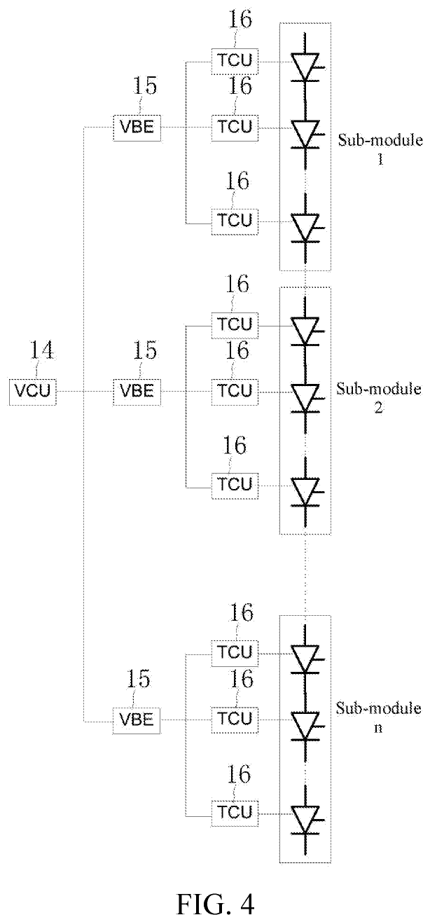

FIG. 4 is a bypass thyristor valve group inspection control apparatus according to the present invention, including: a valve group control unit VCU 14, a valve-based electronic unit VBE 15, and a thyristor control unit TCU 16, and configured to inspect the bypass thyristor valve group 2 connected in parallel to the voltage source converter 1 in FIGS. 1 and 2. The bypass thyristor valve group is divided into a sub-module 1, a sub-module 2, . . . , and a sub-module N, and each sub-module is formed by connecting one or more thyristors in series. When a single sub-module is turned on, the remaining sub-modules which are not turned on can bear a forward voltage during normal operation.

The valve group control unit VCU 14 is configured to: detect a forward voltage born by the bypass thyristor valve group during normal operation; send a control pulse CP to the valve-based electronic units VBE 15 of the sub-module 1, the sub-module 2, . . . , and the sub-module N of the bypass thyristor valve group according to a certain time period; receive a sub-module turn-on signal of the valve-based electronic unit; and if no sub-module turn-on signal of the valve-based electronic units is received, send an alarm signal.

The valve-based electronic unit VBE 15 is configured to receive the control pulse CP of the valve group control unit VCU 14 and a thyristor-born forward voltage signal IP and a thyristor turn-on signal CS of the thyristor control unit TCU 16, send a trigger pulse FP to the thyristor control unit TCU 16, and send the sub-module turn-on signal to the valve group control unit. The sub-module turn-on signal indicates that all thyristors in the sub-module are turned on.

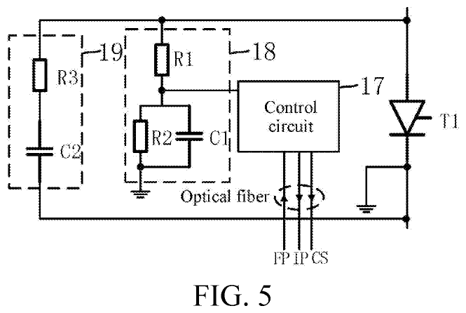

FIG. 5 illustrates a circuit structure diagram of the thyristor control unit TCU 16, including a control circuit 17, a powering loop 18, and a resistance-capacitance discharge loop 19. The control circuit 17 is configured to receive the trigger pulse FP of the valve-based electronic unit VBE 15, send the thyristor-born forward voltage signal IP and the thyristor turn-on signal CS to the valve-based electronic unit VBE 15. The powering loop 18 at least includes two static voltage-sharing resistors R1, R2 and an energy storage capacitor C1, and before the thyristor is turned on, enough energy can be obtained to ensure the normal turn-on of the thyristor. The resistance-capacitance discharge loop 19 at least includes a resistor R3 and a capacitor C2 which are connected in series, and after the thyristor T1 is turned on, enough energy can be obtained to ensure the normal turn-on of the thyristor.

Optionally, the thyristor turn-on signal CS is indirectly determined by means of the thyristor-born forward voltage signal IP, and when the valve group control unit VCU 14 sends the control pulse CP, the thyristor control unit TCU 16 is detected to have the thyristor-born forward voltage signal IP in a short time, which proves the process that the thyristor T1 bears a forward voltage from on to off once.

The control circuit 17 of the thyristor control unit TCU 16 has a protective trigger function, and when the thyristor T1 does not receive the trigger pulse of the valve-based electronic unit, the thyristor T1 is subjected to protective trigger before being broken down.

The foregoing embodiments are for only describing the technical idea of the present invention, and are not intended to limit the scope of protection of the preset invention. Any modification made based on the technical solutions according to the technical idea of the present invention shall fall within the scope of protection of the present invention.

1. A bypass thyristor valve group inspection method for inspecting sub-modules in a bypass thyristor valve group, comprising:
dividing the bypass thyristor valve group into N sub-modules, wherein N is greater than or equal to 2, N is a natural number, and each sub-module is formed by connecting one or more thyristors in series; under the condition that the bypass thyristor valve group bears a forward voltage during normal operation, sequentially triggering the sub-modules according to a certain time period; detecting whether the sub-modules are capable of operating normally or not, and if not, sending an alarm signal.

2. The bypass thyristor valve group inspection method according to claim 1, wherein the bypass thyristor valve group comprises only one bridge arm which is formed by connecting a plurality of thyristors in series, and comprises a corresponding control protection circuit; and the bypass thyristor valve group is configured to bypass a voltage source converter connected in parallel thereto or a voltage source converter on a parallel branch thereof.

3. The bypass thyristor valve group inspection method according to claim 1, wherein the principle of dividing the bypass thyristor valve group into N sub-modules is: when a single sub-module is turned on, the remaining sub-modules which are not turned on can bear the forward voltage during normal operation.

4. The bypass thyristor valve group inspection method according to claim 1, wherein the sequentially triggering the sub-modules according to a certain time period refers to: triggering the sub-modules in sequence or triggering the sub-modules according to a certain probability algorithm, and ensuring that each sub-module is triggered at least once in the certain time period, wherein the certain time period is on the order of second, or minute, or hour, or day, or month, or year.

5. The bypass thyristor valve group inspection method according to claim 1, wherein the detecting whether the sub-modules are capable of operating normally or not is determined based on detecting whether the sub-modules are from an off-state to an on-state, or in an on-state, or from an on-state to an off-state.

6. The bypass thyristor valve group inspection method according to claim 1, wherein the normal operation of the sub-modules refers to that all thyristors in the sub-modules can be normally turned on, or a certain redundancy is set for the sub-modules; if it is detected that the number of thyristors that cannot be turned on in the sub-modules is less than the redundancy, the inspection is continued; and if the bypass thyristor valve group is required to put into operation, the thyristors that cannot be turned on implement current flowing by means of protective trigger or breakdown.

7. A bypass thyristor valve group inspection control apparatus for inspecting sub-modules in a bypass thyristor valve group, comprising a valve group control unit, a valve-based electronic unit, and a thyristor control unit, wherein
the valve group control unit is configured to: divide the bypass thyristor valve group into N sub-modules, wherein N is greater than or equal to 2, N is a natural number, and each sub-module is formed by connecting one or more thyristors in series; detect a forward voltage born by the bypass thyristor valve group during normal operation; sequentially send a control pulse to the valve-based electronic units of different sub-modules of the bypass thyristor valve group according to a certain time period; receive sub-module turn-on signals of the valve-based electronic units; and if no sub-module turn-on signal of the valve-based electronic units is received, send an alarm signal;
the valve-based electronic unit is configured to receive the control pulse of the valve group control unit and a thyristor-born forward voltage signal of the thyristor control unit, receive a thyristor turn-on signal of the thyristor control unit, send a trigger pulse to the thyristor control unit, and send the sub-module turn-on signal to the valve group control unit; and
the thyristor control unit comprises a control circuit, configured to receive the trigger pulse of the valve-based electronic unit, send the thyristor-born forward voltage signal to the valve-based electronic unit, and send the thyristor turn-on signal to the valve-based electronic unit.

8. The bypass thyristor valve group inspection control apparatus according to claim 7, wherein the thyristor control unit further comprises a powering loop and a resistance-capacitance discharge loop; the powering loop at least comprises two static voltage-sharing resistors and an energy storage capacitor, and before the thyristor is turned on, enough energy can be obtained to ensure the normal turn-on of the thyristor; and the resistance-capacitance discharge loop at least comprises a resistor and a capacitor which are connected in series, and after the thyristor is turned on, enough energy can be obtained to ensure the normal turn-on of the thyristor.

9. The bypass thyristor valve group inspection control apparatus according to claim 7, wherein the bypass thyristor valve group comprises only one bridge arm which is formed by connecting a plurality of thyristors in series, and comprises a corresponding control protection circuit; and the bypass thyristor valve group is configured to bypass a voltage source converter connected in parallel thereto or a voltage source converter on a parallel branch thereof.

10. The bypass thyristor valve group inspection control apparatus according to claim 7, wherein the principle of dividing the bypass thyristor valve group into N sub-modules is: when a single sub-module is turned on, the remaining sub-modules which are not turned on can bear a forward voltage during normal operation.

11. The bypass thyristor valve group inspection control apparatus according to claim 7, wherein the sequentially sending a control pulse to the valve-based electronic units of different sub-modules of the bypass thyristor valve group according to a certain time period refers to: triggering the sub-modules in sequence or triggering the sub-modules according to a certain probability algorithm, and ensuring that each sub-module is triggered at least once in the certain time period, wherein the certain time period is on the order of second, or minute, or hour, or day, or month, or year.

12. The bypass thyristor valve group inspection control apparatus according to claim 7, wherein the fact that the valve group control unit receives the sub-module turn-on signal of the valve-based electronic unit is that all thyristors in the sub-modules are turned on, or a certain redundancy is set for the sub-modules, and the thyristors that do not exceed the redundancy in the sub-modules are turned on; and the fact that the valve group control unit does not receive the sub-module turn-on signal of the valve-based electronic unit is that any one or more thyristors in the sub-modules are not turned on, or the thyristors that exceed the redundancy in the sub-modules are not turned on.

13. The bypass thyristor valve group inspection control apparatus according to claim 7, wherein the thyristor turn-on signal sent to the valve-based electronic unit by the thyristor control unit refers to that the thyristor-born forward voltage signal disappears, or current flows through the thyristor, or the thyristor-born forward voltage signal reappears.

14. The bypass thyristor valve group inspection control apparatus according to claim 7, wherein the control circuit of the thyristor control unit has a protective trigger function, and if the thyristor does not receive the trigger pulse of the valve-based electronic unit, before being broken down, the thyristor is subjected to protective trigger.
